(19) United States
(12) Patent Application Publication
(10) Pub. No.: US 2020/0123045 A1
(43) Pub. Date: Apr. 23, 2020

(54) COMPOSITION FOR FORMING ELECTRODE FOR SOLAR CELL INCLUDING NANOTEXTURED SUBSTRATE, ELECTRODE PREPARED USING THE SAME AND SOLAR CELL INCLUDING ELECTRODE PREPARED USING THE SAME

(71) Applicant: SAMSUNG SDI CO., LTD., Yongin-si (KR)

(72) Inventors: Sang Hee PARK, Suwon-si (KR); Ji Seon LEE, Suwon-si (KR); Sung Bin CHO, Suwon-si (KR)

(21) Appl. No.: 16/511,023

(22) Filed: Jul. 15, 2019

(30) Foreign Application Priority Data
Oct. 17, 2018 (KR) 10-2018-0124003

(51) Int. Cl. C03C 8/18; C03C 4/14; C03C 8/10; H01L 31/0236; H01L 31/0224

(52) U.S. Cl. CPC C03C 8/18; C03C 4/14; C03C 8/10; C03C 2209/00; H01L 31/022425; C03C 2204/00; H01L 31/02363

(57) ABSTRACT

A composition for electrodes of solar cells that include a nano-textured substrate and a solar cell including the electrode, the composition including a conductive powder; a glass frit; and an organic vehicle, wherein, when a particle size distribution curve is plotted in a graph with particle size of the conductive powder on the x-axis and fraction of conductive powder particles of corresponding diameter on the y-axis, the conductive powder satisfies Equations 1, 2, and 3.

### CROSS-REFERENCE TO RELATED APPLICATION

Korean Patent Application No. 10-2018-0124003, filed on Oct. 17, 2018, in the Korean Intellectual Property Office, and entitled: “Composition for Forming Electrode for Solar Cell Including Nanotextured Substrate, Electrode Prepared Using the Same and Solar Cell Comprising Electrode Prepared Using the Same,” is incorporated by reference herein in its entirety.

### BACKGROUND

### 1. Field

Embodiments relate to a composition for electrodes of solar cells including a nano-textured substrate, an electrode formed of the same, and a solar cell including the same.

### 2. Description of the Related Art

Solar cells generate electricity using the photovoltaic effect of a PN junction which converts photons of sunlight into electricity. In a solar cell, front and rear electrodes are formed on upper and lower surfaces of a semiconductor wafer or substrate having a PN junction, respectively. Then, the photovoltaic effect at the PN junction is induced by sunlight entering the semiconductor wafer and electrons generated by the photovoltaic effect at the PN junction provide electric current to the outside through the electrodes. The electrodes of the solar cell are formed on the wafer by applying, patterning, and baking a paste composition for solar cell electrodes.

### SUMMARY

The embodiments may be realized by providing a composition for electrodes of solar cells that include a nano-textured substrate, the composition including a conductive powder; a glass frit; and an organic vehicle, wherein, when a particle size distribution curve is plotted in a graph with particle size of the conductive powder on the x-axis and fraction of conductive powder particles of corresponding diameter on the y-axis, the conductive powder satisfies Equations 1, 2, and 3:

about 5%≤(S2/S1)×100≤ about 65% [Equation 1]

about 1%≤(S3/S1)×100≤ about 55% [Equation 2]

about 0.4%≤(S4/S1)×100≤ about 45% [3]

wherein S1 is a total area enclosed by the particle size distribution curve and the x-axis, S2 is an area enclosed by the particle size distribution curve and the x-axis within the particle diameter range of greater than 0 μm and less than or equal to about 2.0 μm, S3 is an area enclosed by the particle size distribution curve and the x-axis within the particle diameter range of greater than 0 μm and less than or equal to about 1.7 μm, and S4 is an area enclosed by the particle size distribution curve and the x-axis within the particle diameter range of greater than 0 μm and less than or equal to about 1.3 μm.

The conductive powder may satisfy Equation 4:

about 5%≤(S5/S1)×100≤ about 40% [Equation4]

wherein S1 is the total area enclosed by the particle size distribution curve and the x-axis, and S5 is an area enclosed by the particle size distribution curve and the x-axis within the particle diameter range of greater than about 1.3 μm and less than or equal to about 1.7 μm.

The conductive powder may satisfy Equation 5:

about 5%≤(S6/S1)×100≤ about 50% [Equation 5]

wherein S1 is the total area enclosed by the particle size distribution curve and the x-axis, and S6 is an area enclosed by the particle size distribution curve and the x-axis within the particle diameter range of greater than about 1.7 μm and less than or equal to about 2.0 μm.

The conductive powder may satisfy Equation 6:

about 35%≤(S7/S1)×100≤ about 95% [Equation 6]

wherein S1 is the total area enclosed by the particle size distribution curve and the x-axis, and S7 is an area enclosed by the particle size distribution curve and the x-axis within the particle diameter range of greater than about 2.0 μm.

The conductive powder may include silver powder.

The composition may include about 60 wt % to about 95 wt % of the conductive powder; about 0.1 wt % to about 20 wt % of the glass fit; and the organic vehicle.

The composition may further include a dispersant, a thixotropic agent, a plasticizer, a viscosity stabilizer, an anti-foaming agent, a pigment, a UV stabilizer, an antioxidant, or a coupling agent.

The embodiments may be realized by providing a solar cell including a nano-textured substrate; and an electrode on the nano-textured substrate, wherein the nano-textured substrate includes a substrate having an average of 5 or more bumps having a height of about 50 nm or more per about 5 μm length in vertical section, and the electrode is prepared from the composition according to an embodiment.

An average maximum distance between a pair of adjacent bumps each having the height of about 50 nm or more per about 5 μm length in vertical section of the nano-textured substrate may be greater than or equal to about 100 nm.

The conductive powder may satisfy Equation 4:

about 5%≤(S5/S1)×100≤ about 40% [Equation 4]

wherein Si is the total area enclosed by the particle size distribution curve and the x-axis, and S5 is an area enclosed by the particle size distribution curve and the x-axis within the particle diameter range of greater than about 1.3 μm and less than or equal to about 1.7 μm.

The conductive powder may satisfy Equation 5:

about 5%≤(S6/S1)×100≤ about 50% [5]

wherein S1 is the total area enclosed by the particle size distribution curve and the x-axis, and S6 is an area enclosed by the particle size distribution curve and the x-axis within the particle diameter range of greater than about 1.7 μm and less than or equal to about 2.0 μm.

The conductive powder may satisfy Equation 6:

about 35%≤(S7/S1)×100≤ about 95% [6]

wherein Si is the total area enclosed by the particle size distribution curve and the x-axis, and S7 is an area enclosed by the particle size distribution curve and the x-axis within the particle diameter range of greater than about 2.0 μm.

The conductive powder may include silver powder.

The composition may include about 60 wt % to about 95 wt % of the conductive powder; about 0.1 wt % to about 20 wt % of the glass fit; and the organic vehicle.

The composition may further include a dispersant, a thixotropic agent, a plasticizer, a viscosity stabilizer, an anti-foaming agent, a pigment, a UV stabilizer, an antioxidant, or a coupling agent.

### BRIEF DESCRIPTION OF THE DRAWINGS

Features will be apparent to those of skill in the art by describing in detail exemplary embodiments with reference to the attached drawings in which:

FIG. 1 illustrates a conceptual view showing a particle size distribution curve and areas S1 and S2 as used herein.

FIG. 2 illustrates an enlarged image of a surface of a nano-textured substrate according to an embodiment.

FIG. 3 illustrates a conceptual view of the definition of height (h) of a bump as used herein.

FIG. 4 illustrates a sectional view of a nano-textured substrate according to one embodiment.

FIG. 5 illustrates a schematic sectional view of a solar cell according to one embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present. Like reference numerals refer to like elements throughout.

One embodiment relates to a composition for electrodes of solar cells that include a nano-textured substrate (hereinafter, also referred to as “composition for solar cell electrodes”). The composition for solar cell electrodes may include, e.g., a conductive powder; a glass fit; and an organic vehicle. In an implementation, when a particle size distribution curve is plotted in a graph with the particle size of the conductive powder on the x-axis and the fraction of conductive powder particles of corresponding diameter on the y-axis, the conductive powder may satisfy Equations 1, 2, and 3.

about 5%≤(S2/S1)×100≤ about 65% [1]

about 1%≤(S3/S1)×100≤ about 55% [2]

about 0.4%≤(S4/S1)×100≤ about 45% [3]

In the Equations, S1 is a total area enclosed by the particle size distribution curve and the x-axis, S2 is an area enclosed by the particle size distribution curve and the x-axis within the particle diameter range of greater than 0 μm and less than or equal to about 2.0 μm, S3 is an area enclosed by the particle size distribution curve and the x-axis within the particle diameter range of greater than 0 μm and less than or equal to about 1.7 μm, and S4 is an area enclosed by the particle size distribution curve and the x-axis within the particle diameter range of greater than 0 μm and less than or equal to about 1.3 μm.

When the conductive powder satisfies Equations 1, 2, and 3, upon formation of an electrode on a nano-textured substrate described in detail below, spaces between bumps of the nano-textured substrate may be sufficiently filled with the composition for solar cell electrodes. In addition, during a baking process, the spaces between the bumps may also be sufficiently filled with the composition for solar cell electrodes. For example, generation of pores at an interface between the electrode and the substrate may be reduced, contact resistance (Re) may be reduced, and series resistance Rs may be improved without an increase in reflectance of the nano-textured substrate, thereby facilitating an increase in solar cell conversion efficiency.

In an implementation, a value of Equation 1, i.e. (S2/S1)×100, a value of Equation 2, i.e. (S3/S1)×100, and a value of Equation 3, i.e. (S4/S1)×100 refer to ratios of areas enclosed by a particle size distribution curve (the particle size distribution curve being plotted in a graph with the particle size of the conductive powder on the x-axis and the fraction of conductive powder particles of corresponding diameter on the y-axis) and the x-axis within the corresponding particle diameter ranges to the total area enclosed by the particle size distribution curve and the x-axis, respectively.

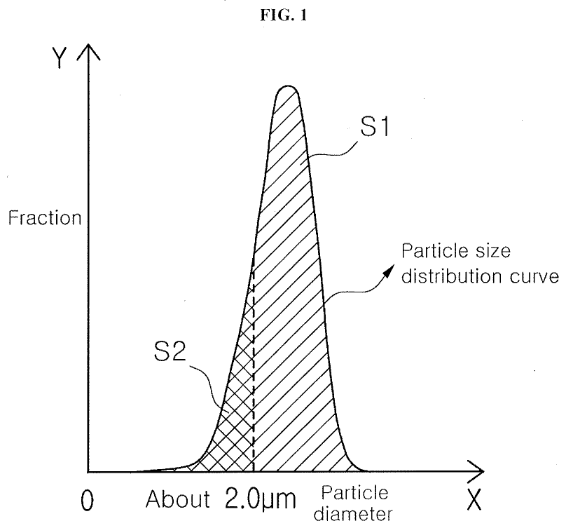

Now, the area ratio S2/S1 will be described in detail with reference to FIG. 1.

Referring to FIG. 1, as to the entirety of the conductive powder of the composition for solar cell electrodes, a particle size distribution curve is plotted in a graph with the particle size of the conductive powder on the x-axis and the fraction (e.g., by weight) of conductive powder particles of corresponding diameter on the y-axis. The area ratio S2/S1 refers to a ratio of an area S2 enclosed by the particle size distribution curve and the x-axis within the corresponding particle diameter range to the total area S1 enclosed by the entire particle size distribution curve and the x-axis. FIG. 1 shows the area S2 corresponding to conductive powder particles having a particle diameter of greater than 0 μm and less than or equal to about 2.0 μm and the area Si enclosed by the entire particle size distribution curve and the x-axis.

It should be understood that FIG. 1 is provided for illustration of the particle size distribution curve, the area S1, and the area S2 and is not to be construed in any way as limiting.

The area ratio S3/S1 and the area ratio S4/S1 may be found in the same manner as in the area ratio S2/S1.

In an implementation, the particle size distribution curve may be obtained by extracting the entirety of the conductive powder from the composition for solar cell electrodes, dispersing 0.25 g of the conductive powder in 5 ml of isopropyl alcohol (IPA) at 25° C. for 3 minutes via ultrasonication (using, e.g., a vortex mixer), measuring the particle size of the conductive powder using a Model 1064D particle size analyzer (CILAS Co., Ltd.), and plotting the measured values in a graph with the particle size of the conductive powder on the x-axis and the fraction of conductive powder particles of corresponding diameter on the y-axis.

In an implementation, the value of Equation 1, i.e. (S2/S1)×100 may be, e.g., about 6% to about 60%. the value of Equation 2, i.e. (S3/S1)×100 may be, e.g., about 1.5% to about 50%. and the value of Equation 3, i.e. (S4/S1)×100 may be, e.g., about 0.5% to about 40%.

Even when the conductive powder satisfies Equations 1 and 2, if the value of Equation 3 were to be less than about 0.4%, it could be difficult to fill the spaces between bumps of a nano-textured silicon substrate with the conductive powder, and pores could be generated at an interface between an electrode and the substrate, thereby causing increase in contact resistance. If the value of Equation 3 were to exceed about 45%, the composition could have poor printability due to an excess of fine conductive powder particles.

Even when the conductive powder satisfies Equations 1 and 3, if the value of Equation 2 were to be less than about 1%, it could be difficult to fill the space between bumps of a nano-textured silicon substrate with the conductive powder, and pores could be generated at an interface between an electrode and the substrate, thereby causing increase in contact resistance. If the value of Equation 2 were to exceed about 55%, the composition could have poor printability due to an excess of fine conductive powder particles.

Even when the conductive powder satisfies Equations 2 and 3, if the value of Equation 1 were to be less than about 5%, it could be difficult to fill the space between bumps of a nano-textured silicon substrate with silver particles, and pores could generated at an interface between an electrode and the substrate, thereby causing increase in contact resistance. If the value of Equation 1 were to exceed about 65%, the composition could have poor printability due to an excess of fine silver particles.

In an implementation, the conductive powder may satisfy the following Equation: (S4/S1)×100 (value of Equation 1)<(S3/S1)×100 (value of Equation 2)<(S2/S1)×100 (value of Equation 3).

In an implementation, the conductive powder may have an asymmetric particle size distribution curve.

In an implementation, conductive powder may further satisfy Equation 4.

about 5%≤(S5/S1)×100≤ about 40% [4]

In Equation 4, Si is the total area enclosed by the particle size distribution curve and the x-axis and S5 is an area enclosed by the particle size distribution curve and the x-axis within the particle diameter range of greater than about 1.3 μm and less than or equal to about 1.7 μm.

In an implementation, the value of Equation 4, i.e. (S5/S1)×100 may be, e.g., about 10% to about 30%. Within this range, the conductive powder can provide the most efficient contact resistance.

In an implementation, the conductive powder may further satisfy Equation 5.

about 5%≤(S6/S1)×100≤ about 50% [5]

In Equation 5, S1 is the total area enclosed by the particle size distribution curve and the x-axis and S6 is an area enclosed by the particle size distribution curve and the x-axis within the particle diameter range of greater than about 1.7 μm and less than or equal to about 2.0 μm).

In an implementation, the value of Equation 5, i.e. (S6/S1)×100, may be, e.g., about 15% to about 40%. Within this range, the conductive powder can provide the most efficient contact resistance.

In an implementation, the conductive powder may further satisfy Equation 6.

about 35%≤(S7/S1)×100≤ about 95% [6]

In Equation 6, Si is the total area enclosed by the particle size distribution curve and the x-axis and S7 is an area enclosed by the particle size distribution curve and the x-axis within the particle diameter range of greater than about 2.0

In an implementation, S7 may be an area enclosed by the particle size distribution curve and the x-axis within the particle diameter range of greater than about 2.0 μm and less than or equal to about 8.0 μm. In an implementation, the value of Equation 6, i.e. (S7/S1)×100, may be, e.g., about 35% to about 60%. Within this range, the amount of conductive powder particles having a diameter of 2.0 μm or less can fall within the range according to an embodiment, whereby an electrode formed of the composition for solar cell electrodes may have sufficient conductivity without increase in reflectance of a substrate.

In an implementation, the conductive powder may include the same or different types of conductive powders. In an implementation, the conductive powder may include the same types of conductive powders. In an implementation, the conductive powder may be or include, e.g., silver (Ag), gold (Au), palladium (Pd), platinum (Pt), copper (Cu). chromium (Cr), cobalt (Co), aluminum (Al), tin (Sn), lead (Pb), zinc (Zn), iron (Fe), iridium (Ir), osmium (Os), rhodium (Rh), tungsten (W), molybdenum (Mo), or nickel (Ni). In an implementation, the conductive powder may be silver powder.

The conductive powder may have various particle shapes, e.g., a spherical, flake or amorphous particle shape. In an implementation, the conductive powder may have a spherical particle shape.

In an implementation, the conductive powder may be present in an amount of about 60 wt % to about 95 wt %, e.g. about 70 wt % to about 95 wt % or about 85 wt % to about 95 wt %, based on a total weight of the composition for solar cell electrodes. Within this range, the composition may help improve solar cell conversion efficiency and may be easily prepared in paste form. In an implementation, the conductive powder may be present in an amount of about 60 wt %, 61 wt %, 62 wt %, 63 wt %, 64 wt %, 65 wt %, 66 wt %, 67 wt %, 68 wt %, 69 wt %, 70 wt %, 71 wt %, 72 wt %, 73 wt %, 74 wt %, 75 wt %, 76 wt %, 77 wt %, 78 wt %, 79 wt %, 80 wt %, 81 wt %, 82 wt %, 83 wt %, 84 wt %, 85 wt %, 86 wt %, 87 wt %, 88 wt %, 89 wt %, 90 wt %, 91 wt %, 92 wt %, 93 wt %, 94 wt %, or 95 wt %, based on the total weight of the composition for solar cell electrodes.

Next, a nano-textured substrate according to an embodiment will be described.

The nano-textured substrate may be a substrate that constitutes a light receiving surface of a solar cell.

Generally, a substrate constituting the light receiving surface may have a textured structure to improve light receiving efficiency. The textured structure may be formed by surface treatment of a front surface of the substrate using a suitable method, e.g., as etching. The textured structure may condense light entering the front surface of the substrate. The textured structure may have a pyramidal shape, a square honeycomb shape, a triangular honeycomb shape, or the like. For example, the textured structure allows an increased amount of light to reach a PN junction and can reduce light reflectance, thereby minimizing optical loss.

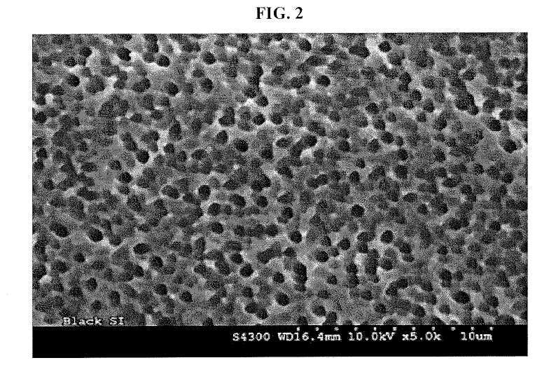

The nano-textured substrate according to an embodiment may be further formed with bumps after or during formation of the textured structure to further reduce reflection of sunlight from the surface of the substrate. FIG. 2 illustrates an image of the surface of the nano-textured substrate. Referring to FIG. 2, it may be seen that the nano-textured substrate had increased surface roughness.

The nano-textured substrate according to an embodiment may have increased surface roughness to reduce sunlight reflectance, thereby improving solar cell conversion efficiency. In addition, an increase in surface roughness of the nano-textured substrate facilitates an increase in contact area between an electrode and the substrate, thereby reducing contact resistance.

In an implementation, the nano-textured substrate may be a substrate that is formed with an average of 5 or more bumps having a height (h) of about 50 nm or more per about 5 um length in vertical section.

In an implementation, the nano-textured substrate may have an average of 5 to 100, e.g., 5 to 50, bumps having a height (h) of about 50 nm or more per about 5 um length in vertical section.

As used herein, the term “bump” refers to a portion protruding from the surface of the substrate to form surface roughness, and may be a protrusion at least partially having a curved surface. In an implementation, the bump may be symmetrical or asymmetrical and may have a parabolic, semi-elliptical, semicircular, or at least partially curved polygonal cross-section. In an implementation, one bump may be formed independently of adjacent bumps, a plurality of bumps may be consecutively formed in one direction in cross-section of the substrate, or a plurality of bumps may be consecutively formed in a stacked manner in a vertical direction in cross-section of the substrate. In an implementation, the shape and arrangement of the bumps may be such that the surface roughness described above can be secured by the bumps.

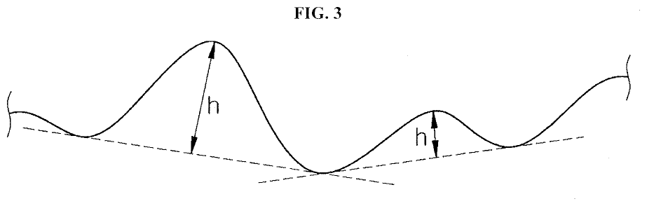

Next, the term “height (h)” will be described with reference to FIG. 3 and FIG.

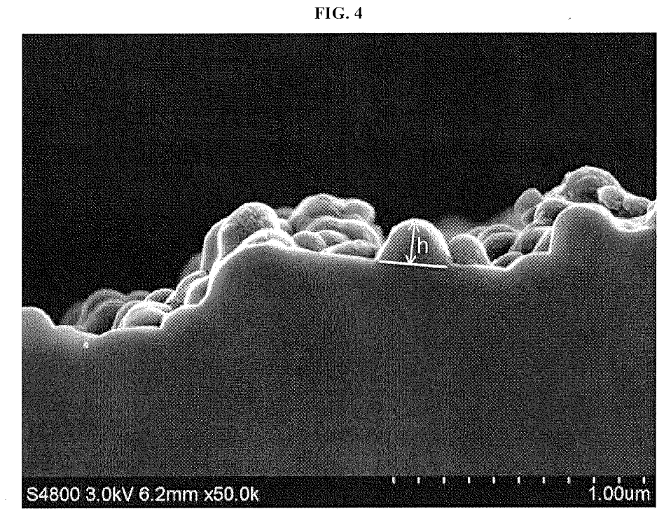

4. Referring to FIG. 3, “height (h)” refers to a distance from a reference line connecting two lowermost points of the bump to the top of the bump. In FIG. 3, the dotted line indicates the reference line. Here, the reference line may or may not be parallel to a lowermost plane of the nano-textured substrate. FIG. 3 and FIG. 4 show the case in which the reference line is not parallel to the lowermost plane.

In an implementation, an average maximum distance between a pair of adjacent bumps each having a height (h) of about 50 mn or more per about 5 μm length in vertical section of the nano-textured substrate may be, e.g., about 100 nm or more. In an implementation, the maximum distances may be the same or different from one another.

The height of the bumps of the nano-textured substrate and/or the number of bumps and/or the distance between the bumps may be adjusted by, e.g., wet etching or dry etching of the substrate.

An example of the wet etching may include metal-catalyzed chemical etching (MCCE). For example, saw damage caused by diamond sawing may be removed through a saw damage removal (SDR) process, followed by formation of a nano-texture through MCCE. Herein, MCCE is a process of gradually etching a surface of a silicon substrate with silver nitrate (AgNO₃) and removing silver nanoparticles, which are by-products of the etching process. An example of the dry etching may include reactive ion etching (RIE) in which a silicon wafer subjected to SDR is dry-etched using plasma. Here, SF₆/O₂ gas is used to generate plasma and a SiOF layer used as a mask needs to be removed.

The composition for solar cell electrodes may further include a glass frit and an organic vehicle. In an implementation, the composition for solar cell electrodes may further include an additive.

Glass Frit

The glass frit may form metal crystal grains in an emitter region by etching an anti-reflection layer and melting the conductive powder during a baking process of the composition for solar cell electrodes. In an implementation, the glass frit may help improve adhesion of the conductive powder to a wafer and may be softened to decrease the baking temperature during the baking process.

The glass frit may have a glass transition temperature (Tg) of about 150° C. to about 450° C., e.g., about 180° C. to about 400° C. Within this range, the composition may be well deposited on a silicon substrate having bumps and may have good contact efficiency, thereby further improving electrical properties such as contact resistance and serial resistance. The glass frit may have a crystallization temperature (Tc) of about 300° C. to about 650° C., e.g., about 300° C. to about 600° C. In addition, the glass frit may have a melting point (Tm) of about 350° C. to about 700° C., e.g., about 350° C. to about 650° C. Within these ranges of Tc and Tm, an electrode formed of the composition may have further improved contact efficiency with the silicon substrate.

The glass frit may include at least one elemental metal or metalloid, e.g., tellurium (Te), lithium (Li), zinc (Zn), bismuth (Bi), lead (Pb), sodium (Na), phosphorus (P), germanium (Ge), gallium (Ga), cerium (Ce), iron (Fe), silicon (Si), tungsten (W), magnesium (Mg), molybdenum (Mo), cesium (Cs), strontium (Sr), titanium (Ti), tin (Sn), indium (In), vanadium (V), barium (Ba), nickel (Ni), copper (Cu), potassium (K), arsenic (As), cobalt (Co), zirconium (Zr), manganese (Mn), aluminum (Al), or boron (B). The glass frit may be formed of an oxide of the at least one elemental metal or metalloid.

In an implementation, the glass frit may include, e.g., a Bi—Te—O glass frit, a Pb—Bi—O glass frit, a Pb—Te—O glass frit, a Te—B—O glass frit, a Te—Ag—O glass frit, a Pb—Si—O glass frit, a Bi—Si—O glass frit, a Te—Zn—O glass frit, a Bi—B—O glass frit, a Pb—B—O glass frit, a Bi—Mo—O glass frit, a Mo—B—O glass fit, or a Te—Si—O glass fit. In this case, a solar cell electrode formed of the composition may exhibit good balance between electrical properties.

The glass fit may be prepared by a suitable method. For example, the glass fit may be prepared by mixing the aforementioned components using a ball mill or a planetary mill, melting the mixture at about 900° C. to about 1,300° C., and quenching the melted mixture to 25° C., followed by pulverizing the obtained product using a disk mill, a planetary mill or the like. The glass frit may have an average particle diameter (D50) of about 0.1 μm to about 10 μm.

The glass fit may be present in an amount of about 0.1 wt % to about 20 wt %, e.g., about 0.5 wt % to about 10 wt %, based on the total weight of the composition for solar cell electrodes. Within this range, the glass frit may secure stability of a PN junction under various sheet resistances, minimize resistance, and ultimately improve solar cell efficiency. In an implementation, the glass frit may be present in an amount of about 0.1 wt %, 0.2 wt %, 0.3 wt %, 0.4 wt %, 0.5 wt %, 0.6 wt %, 0.7 wt %, 0.8 wt %, 0.9 wt %, 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, or 20 wt %, based on the total weight of the composition for solar cell electrodes.

Organic Vehicle

The organic vehicle may impart suitable viscosity and rheological characteristics for printing to the composition for solar cell electrodes through mechanical mixing with inorganic components of the composition.

The organic vehicle may be a suitable organic vehicle used in a composition for solar cell electrodes and may include a binder resin, a solvent, or the like.

The binder resin may include acrylate resins or cellulose resins. Ethyl cellulose may be used as the binder resin. In an implementation, the binder resin may include ethyl hydroxyethyl cellulose, nitrocellulose, blends of ethyl cellulose and phenol resins, alkyd resins, phenol resins, acrylate ester resins, xylene resins, polybutene resins, polyester resins, urea resins, melamine resins, vinyl acetate resins, wood rosin, polymethacrylates of alcohols, or the like.

The solvent may include, e.g., hexane, toluene, ethyl cellosolve, cyclohexanone, butyl cellosolve, butyl carbitol (diethylene glycol monobutyl ether), dibutyl carbitol (diethylene glycol dibutyl ether), butyl carbitol acetate (diethylene glycol monobutyl ether acetate), propylene glycol monomethyl ether, hexylene glycol, terpineol, methylethylketone, benzylalcohol, γ-butyrolactone, or ethyl lactate. These may be used alone or as a mixture thereof.

The organic vehicle may be present in a balance amount to make 100 wt % of the composition for solar cell electrodes. In an implementation, the organic vehicle may be present in an amount of about 1 wt % to about 30 wt % in based on the total weight of the composition for solar cell electrodes. Within this range, the organic vehicle may provide sufficient adhesive strength and good printability to the composition. In an implementation, the organic vehicle may be present in an amount of about 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, or 30 wt % in the composition for solar cell electrodes.

Additive

The composition for solar cell electrodes according to an embodiment may further include a suitable additive to enhance flowability, processability and stability, as desired. The additive may include, e.g., a dispersant, a thixotropic agent, a plasticizer. a viscosity stabilizer, an anti-foaming agent, a pigment, a UV stabilizer, an antioxidant, a coupling agent, and the like. These may be used alone or as a mixture thereof. The additive may be present in an amount of about 0.1 wt % to about 5 wt % based on the total weight of the composition for solar cell electrodes, although the content of the additive may be changed, as needed. In an implementation, the additive may be present in an amount of about 0.1 wt %, 0.2 wt %, 0.3 wt %, 0.4 wt %, 0.5 wt %, 0.6 wt %, 0.7 wt %, 0.8 wt %, 0.9 wt %, 1 wt %, 2 wt %, 3 wt %, 4 wt %, or 5 wt %, based on the total weight of the composition for solar cell electrodes.

Next, a solar cell according to an embodiment will be described.

A solar cell according to an embodiment may include an electrode formed of the composition for solar cell electrodes as described above. In an implementation, the solar cell includes a nano-textured silicon substrate and an electrode formed on the silicon substrate, wherein the nano-textured silicon substrate includes a substrate having 5 or more bumps having a height (h) of about 50 nm or more per about 5 μm length in vertical section, and the electrode is prepared from the composition for solar cell electrodes according to an embodiment.

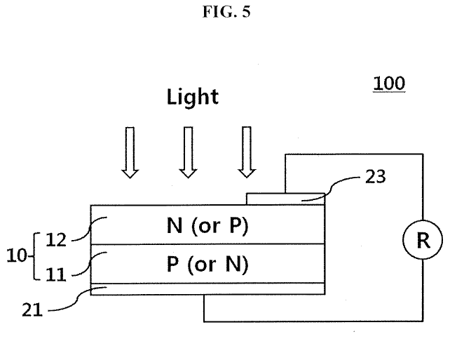

Now, a solar cell according to one embodiment will be described with reference to FIG. 5. FIG. 5 illustrates a schematic view of a solar cell according to one embodiment.

The solar cell 100 according to an embodiment may include a silicon substrate 10 and an electrode formed on the silicon substrate 10.

The silicon substrate 10 may be a substrate with a PN junction thereon or therein. A front electrode 23 may be formed on a front surface of the silicon substrate 10 and a rear electrode 21 may be formed on a back surface of the silicon substrate 10. Herein, the front surface refers to a light receiving surface and the rear surface refers to a surface of the substrate opposite the front surface.

The silicon substrate 10 may include a semiconductor substrate 11 and an emitter 12. The silicon substrate 10 may be a substrate prepared by doping one surface of a p-type semiconductor substrate 11 with an n-type dopant to form an n-type emitter 12. In an implementation, the substrate 10 may be a substrate prepared by doping one surface of an n-type semiconductor substrate 11 with a p-type dopant to form a p-type emitter 12. Here, the semiconductor substrate 11 may be either a p-type substrate or an n-type substrate. The p-type substrate may be a semiconductor substrate 11 doped with a p-type dopant, and the n-type substrate may be a semiconductor substrate 11 doped with an n-type dopant.

In an implementation, the semiconductor substrate 11 may be formed of crystalline silicon or a compound semiconductor. Here, the crystalline silicon may be monocrystalline or polycrystalline. As the crystalline silicon, e.g., a silicon wafer may be used.

Here, the p-type dopant may be a material including Group III elements of the periodic table, such as boron, aluminum, or gallium. In addition. the n-type dopant may be a material including Group V elements of the periodic table. such as phosphorus, arsenic or antimony.

The semiconductor substrate 11 may be formed by the method described above relating to manufacture of the nano-textured substrate. In this way, the semiconductor substrate 11 and thus the silicon substrate 10 can have the aforementioned number of bumps.

The front electrode 23 on the surface of the silicon substrate 10 may be formed of the composition for solar cell electrodes according to an embodiment. For example, a preliminary process of forming the front electrode may be performed by depositing the composition for solar cell electrodes on the front surface of the silicon substrate by printing, followed by drying. Then, the front electrode may be formed by baking at about 400° C. to about 950° C., e.g., at about 750° C. to about 950° C., for about 30 seconds to 180 seconds. The rear electrode may be formed of the composition for solar cell electrodes according to an embodiment or another suitable composition for solar cell electrodes by a suitable method.

In an implementation, the front electrode and the rear electrode may be formed in a bus bar pattern.

In an implementation, an anti-reflection film may be further formed on the front surface of the silicon substrate. The anti-reflection film may further reduce sunlight reflectance, thereby further enhancing anti-reflection efficiency of the substrate. The anti-reflection film may include, e.g., oxides including aluminum oxide (Al₂O₃), silicon oxide (SiO₂), titanium oxide (TiO₂ or TiO₄), magnesium oxide (MgO), cerium oxide (CeO₂), or combinations thereof; nitrides including aluminum nitride (AlN), silicon nitride (SiNx), titanium nitride (TiN), or combinations thereof; or oxynitrides including aluminum oxynitride (AlON), silicon oxynitride (SiON), titanium oxynitride (TiON), or combinations thereof. The front electrode may be formed after formation of the anti-reflection film on the surface of the silicon substrate.

In an implementation, a back surface field layer and/or an anti-reflection film may be further formed on the back surface of the silicon substrate 10.

The back surface field layer may be a layer formed by doping the back surface of the semiconductor substrate 11 with a high concentration of dopant. The back surface field layer may have a higher doping concentration than the semiconductor substrate 11, and there may be a potential difference between the back surface field layer and the semiconductor substrate. This may help prevent electrons generated in the semiconductor substrate from moving toward the back surface of the substrate and recombining with metals, thereby reducing electron loss. As a result, both open-circuit voltage (Voc) and fill factor may be increased, thereby improving solar cell efficiency. When the semiconductor substrate is a p-type semiconductor substrate, the back surface field layer may be formed of a p-type dopant, and when the semiconductor substrate is an n-type semiconductor substrate, the back surface field layer may be formed of an n-type dopant.

The anti-reflection film may help reduce light reflectance while increasing absorption of light at a specific wavelength and enhances contact efficiency with silicon present on the surface of the silicon substrate, thereby improving solar cell efficiency. The anti-reflection film may have an uneven surface, or may have the same form as that of the textured structure formed on the substrate. In this way, reflection loss of incident light may be reduced. The anti-reflection film on the back surface of the substrate may be formed of the same material as that of the anti-reflection film on the front surface of the substrate described above and may be formed in a single layer or multiple layers, e.g., two or more layers. The rear electrode may be formed after the back surface field layer and the anti-reflection film are sequentially formed on the back surface of the silicon substrate.

The anti-reflection film may be formed by, e.g., atomic layer deposition (ALD), vacuum deposition, atmospheric pressure chemical vapor deposition, plasma enhanced chemical vapor deposition, or the like.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLE 1

As an organic binder, 1.0 part by weight of ethyl cellulose (STD4, Dow Chemical Company) was sufficiently dissolved in 5.6 parts by weight of terpineol at 60° C., and then 88.90 parts by weight of a conductive powder (silver powder) having a particle size distribution shown in Table 1, 3.1 parts by weight of a Pb—Te—O glass frit having an average particle diameter of 1.0 μm (Tg: 275° C., Tc: 410° C., Tm: 530° C.), 0.5 parts by weight of a surface tension modifier (KF-96, Shin-Etsu Chemicals Ltd.), 0.5 parts by weight of a dispersant (BYK102, BYK-Chemie), and 0.4 parts by weight of a thixotropic agent (Thixatrol ST, Elementis Co., Ltd.) were added to the binder solution, followed by mixing and kneading in a 3-roll kneader, thereby preparing a composition for solar cell electrodes.

0.25 g of the conductive powder was dispersed in 5 ml of isopropyl alcohol (IPA) at 25° C. for 3 minutes via ultrasonication (using a vortex mixer), followed by measurement of the particle diameter of the conductive powder using a Model 1064D particle size analyzer (CILAS Co., Ltd.), and then the measured values were plotted in a graph with the particle diameter of the conductive powder on the x-axis and the fraction of conductive powder particles of corresponding diameter on the y-axis, thereby obtaining a particle size distribution curve. Then, the values of Equations 1, 2, and 3 were found, and results are shown in Table 1.

### EXAMPLES 2 to 9

Compositions for solar cell electrodes were prepared in the same manner as in Example 1 except that the kind of conductive powder was changed as listed in Table 1.

### COMPARATIVE EXAMPLE 1 to 6

Compositions for solar cell electrodes were prepared in the same manner as in Example 1 except that the kind of conductive powder was changed as listed in Table 1.

A solar cell was fabricated using each of the compositions for solar cell electrodes prepared in Examples and Comparative Examples and then was evaluated as to the properties shown in Table 1. Results are shown in Table 1.

Fabrication of Solar Cell

Each of the compositions for solar cell electrodes prepared in the Examples and Comparative Examples was deposited over a front surface of a multi-crystalline wafer, which was prepared by texturing a front surface of a wafer (a p-type wafer doped with boron (B)), forming an n⁺ layer of POCL₃ on the textured surface, and forming a passivation layer of aluminum oxide on the n⁺ layer by screen printing in a predetermined pattern, followed by drying in an IR drying furnace at 300° C. for 1 minute. Then, an aluminum paste was printed on a back surface of the wafer and dried in the IR drying furnace at 300° C. for 1 minute as above, thereby forming a finger electrode pattern and a bus electrode pattern. A cell formed according to this procedure was subjected to baking at a temperature of 940° C. for 50 seconds in a belt-type baking furnace, thereby fabricating a solar cell.

Here, the texturing process was performed by dry etching as described above, thereby obtaining a nano-textured substrate having bumps, wherein the number of bumps was the same as shown in Table 1. The number of bumps having a height (h) of 50 nm or more per 5 μm length in vertical section of the substrate was measured 10 times using an electron microscope image of the cross-section of the fabricated solar cell, followed by averaging the values.

The fabricated solar cell was evaluated as to contact resistance (Re, mΩ), fill factor (FF, %) and conversion efficiency (Eff., %) using a solar cell efficiency tester CT-801 (Pasan Co., Ltd.).

TABLE 1

| | Particle size distribution of conductive powder | | | | | | |
|---|---|---|---|---|---|---|---|
| | Value of | Value of | Value of | | | | |
| | Equation 3 | Equation 2 | Equation 1 | | | | |
| | ((S4/S1) × 100) | ((S3/S1) × 100) | ((S2/S1) × 100) | Number of | Rs | FF | Eff |
| Item | (%) | (%) | (%) | bumps | (mΩ) | (%) | (%) |
| Example 1 | 25.1 | 45.4 | 53.2 | 5 | 1.69 | 80.99 | 20.40 |
| Example 2 | 30.6 | 53.8 | 63.5 | 7 | 1.70 | 80.68 | 20.45 |
| Example 3 | 0.7 | 2.7 | 8.2 | 10 | 1.79 | 81.05 | 20.12 |
| Example 4 | 10.1 | 21.5 | 39.5 | 11 | 1.74 | 80.99 | 20.34 |
| Example 5 | 31.2 | 42.5 | 63.8 | 8 | 1.42 | 81.21 | 20.18 |
| Example 6 | 22.6 | 35.6 | 53.2 | 9 | 1.55 | 81.03 | 20.20 |
| Example 7 | 42.6 | 54.2 | 64.1 | 18 | 1.52 | 81.12 | 20.25 |
| Example 8 | 37.5 | 46.5 | 62.5 | 6 | 1.59 | 81.07 | 20.29 |
| Example 9 | 1.9 | 4.5 | 11.8 | 13 | 1.76 | 81.33 | 20.14 |
| Comparative | 0.3 | 1 | 5 | 10 | 4.33 | 76.55 | 18.19 |
| Example 1 | | | | | | | |
| Comparative | 32 | 46.8 | 67 | 21 | 2.12 | 79.84 | 19.71 |
| Example 2 | | | | | | | |
| Comparative | 0.2 | 0.9 | 5 | 10 | 4.55 | 76.15 | 17.92 |
| Example 3 | | | | | | | |
| Comparative | 10.9 | 56.2 | 63 | 19 | 2.04 | 79.87 | 19.86 |
| Example 4 | | | | | | | |
| Comparative | 0.2 | 2 | 4 | 17 | 5.23 | 75.64 | 17.54 |
| Example 5 | | | | | | | |
| Comparative | 41 | 55.1 | 65.3 | 8 | 2.58 | 79.23 | 19.67 |
| Example 6 | | | | | | | |

As shown in Table 1, it may be seen that the composition for solar cell electrodes according to Examples 1-9 reduces contact resistance with the nano-textured substrate, thereby increasing solar cell conversion efficiency. In addition, the composition for solar cell electrodes according to Examples 1-9 had good printability while minimizing increase in reflectance of a solar cell.

By way of summation and review, in order to improve solar cell efficiency, an anti-reflection film may be formed on a front surface and/or back surface of a silicon substrate of a solar cell. Such an anti-reflection film may help reduce reflection of incident sunlight, but does not consider a relation between the anti-reflection film and an electrode contacting the substrate, and the improvement in solar cell efficiency may be limited. With the recent development of a textured silicon substrate, a composition for solar cell electrodes according to an embodiment may be suitable for use in such a textured silicon substrate.

One or more embodiments may provide a composition for electrodes of solar cells including a nano-textured substrate, which may have good printability and may help reduce contact resistance, thereby improving solar cell conversion efficiency while suppressing increase in reflectance of the substrate.

One or more embodiments may provide a composition for solar cell electrodes which can reduce contact resistance with a nano-textured substrate, thereby improving conversion efficiency of a solar cell.

One or more embodiments may provide a composition for solar cell electrodes which has good printability on a nano-textured substrate and can minimize an increase in reflectance of a solar cell.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics. and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A composition for electrodes of solar cells that include a nano-textured substrate, the composition comprising:
a conductive powder;
a glass frit; and
an organic vehicle,
wherein, when a particle size distribution curve is plotted in a graph with particle size of the conductive powder on the x-axis and fraction of conductive powder particles of corresponding diameter on the y-axis, the conductive powder satisfies Equations 1, 2, and 3:
about 5%≤(S2/S1)×100≤ about 65% [1]
about 1%≤(S3/S1)×100≤ about 55% [2]
about 0.4%≤(S4/S1)×100≤ about 45% [3]
wherein S1 is a total area enclosed by the particle size distribution curve and the x-axis, S2 is an area enclosed by the particle size distribution curve and the x-axis within the particle diameter range of greater than 0 μm and less than or equal to about 2.0 μm, S3 is an area enclosed by the particle size distribution curve and the x-axis within the particle diameter range of greater than 0 μm and less than or equal to about 1.7 μm, and S4 is an area enclosed by the particle size distribution curve and the x-axis within the particle diameter range of greater than 0 μm and less than or equal to about 1.3 μm.

2. The composition as claimed in claim 1, wherein the conductive powder satisfies Equation 4:
about 5%≤(S5/S1)×100≤ about 40% [4]
wherein S1 is the total area enclosed by the particle size distribution curve and the x-axis, and S5 is an area enclosed by the particle size distribution curve and the x-axis within the particle diameter range of greater than about 1.3 μm and less than or equal to about 1.7 μm.

3. The composition as claimed in claim 1, wherein the conductive powder satisfies Equation 5:
about 5%≤(S6/S1)×100≤ about 50% [5]
wherein S1 is the total area enclosed by the particle size distribution curve and the x-axis, and S6 is an area enclosed by the particle size distribution curve and the x-axis within the particle diameter range of greater than about 1.7 μm and less than or equal to about 2.0 μm.

4. The composition as claimed in claim 1, wherein the conductive powder satisfies Equation 6:
about 35%≤(S7/S1)×100≤ about 95% [6]
wherein S1 is the total area enclosed by the particle size distribution curve and the x-axis, and S7 is an area enclosed by the particle size distribution curve and the x-axis within the particle diameter range of greater than about 2.0 μm.

5. The composition as claimed in claim 1, wherein the conductive powder includes silver powder.

6. The composition as claimed in claim 1, wherein the composition includes:
about 60 wt % to about 95 wt % of the conductive powder;
about 0.1 wt % to about 20 wt % of the glass frit; and
the organic vehicle.

7. The composition as claimed in claim 1, further comprising a dispersant, a thixotropic agent, a plasticizer, a viscosity stabilizer, an anti-foaming agent, a pigment, a UV stabilizer, an antioxidant, or a coupling agent.

8. A solar cell, comprising:
a nano-textured substrate; and
an electrode on the nano-textured substrate,
wherein:
the nano-textured substrate includes a substrate having an average of 5 or more bumps having a height of about 50 nm or more per about 5 μm length in vertical section, and
the electrode is prepared from the composition as claimed in claim 1.

9. The solar cell as claimed in claim 8, wherein an average maximum distance between a pair of adjacent bumps each having the height of about 50 nm or more per about 5 μm length in vertical section of the nano-textured substrate is greater than or equal to about 100 nm.

10. The solar cell as claimed in claim 8, wherein the conductive powder satisfies Equation 4:
about 5%≤(S5/S1)×100≤ about 40% [4]
wherein S1 is the total area enclosed by the particle size distribution curve and the x-axis, and S5 is an area enclosed by the particle size distribution curve and the x-axis within the particle diameter range of greater than about 1.3 μm and less than or equal to about 1.7 μm.

11. The solar cell as claimed in claim 8, wherein the conductive powder satisfies Equation 5:
about 5%≤(S6/S1)×100≤ about 50% [5]
wherein S1 is the total area enclosed by the particle size distribution curve and the x-axis, and S6 is an area enclosed by the particle size distribution curve and the x-axis within the particle diameter range of greater than about 1.7 μm and less than or equal to about 2.0 μm.

12. The solar cell as claimed in claim 8, wherein the conductive powder satisfies Equation 6:
about 35%≤(S7/S1)×100≤ about 95% [6]
wherein S1 is the total area enclosed by the particle size distribution curve and the x-axis, and S7 is an area enclosed by the particle size distribution curve and the x-axis within the particle diameter range of greater than about 2.0 μm.

13. The solar cell as claimed in claim 8, wherein the conductive powder includes silver powder.

14. The solar cell as claimed in claim 8, wherein the composition includes:
about 60 wt % to about 95 wt % of the conductive powder;
about 0.1 wt % to about 20 wt % of the glass frit; and
the organic vehicle.

15. The solar cell as claimed in claim 8, wherein the composition further includes a dispersant, a thixotropic agent, a plasticizer, a viscosity stabilizer, an anti-foaming agent, a pigment, a UV stabilizer, an antioxidant, or a coupling agent.
